(19) United States
(12) Patent Application Publication
(10) Pub. No.: US 2013/0164661 A1
(43) Pub. Date: Jun. 27, 2013

(54) METHOD FOR MAKING A RETARDATION FILM

(71) Applicants: Chien-Cheng Chang, Taipei City (TW); Chiu-Fang Chen, Taipei City (TW); Da-Ren Chiou, TAipei City (TW); Wei-Che Hung, Taipei City (TW)

(72) Inventors: Chien-Cheng Chang, Taipei City (TW); Chiu-Fang Chen, Taipei City (TW); Da-Ren Chiou, TAipei City (TW); Wei-Che Hung, Taipei City (TW)

(73) Assignee: FAR EASTERN NEW CENTURY CORPORATION, Taipei City (TW)

(21) Appl. No.: 13/617,559

(22) Filed: Sep. 14, 2012

(30) Foreign Application Priority Data
Dec. 21, 2011 (TW) 100147715

(51) Int. Cl. G03F 7/20

(52) U.S. Cl. 430/20

(57) ABSTRACT

A method for making a retardation film includes: (a) forming a photo-alignment layer on a substrate; (b) exposing the photo-alignment layer such that first and second regions of the alignment surface are oriented in a first alignment direction; (c) disposing a patterned mask over the photo-alignment layer such that the first regions of the alignment surface are shielded; (d) exposing the second regions such that the second regions are oriented in a second alignment direction, and the first regions remain oriented in the first alignment direction; (e) coating liquid crystal molecules over the alignment surface; and (f) curing the liquid crystal molecules.

### CROSS-REFERENCE TO RELATED APPLICATION

This application claims priority of Taiwanese application no. 100147715, filed on Dec. 21, 2011.

### BACKGROUND OF THE INVENTION

1. Field of the Invention

This invention relates to a method for making a retardation film, more particularly to a method for making a retardation film that has two different alignment directions.

2. Description of the Related Art

The so-called birefringence property of liquid crystal molecules refers to that the liquid crystal molecules have different refractive indices in different axes. Because of the birefringence property, when light passes through the liquid crystal molecules, the polarizing direction of the light can be varied to cause an optical retardation (i.e., phase difference).

Because liquid crystal molecules, after being oriented, have a substantially uniform birefringence, the same can be used for forming retardation films.

Many methods for making a retardation film have been proposed, such as those disclosed in U.S. Pat. No. 6,624,863, U.S. Pat. No. 5,926,241, and Japanese Patent Publication No.2001-100150. However, the proposed methods are relatively complex processes, and retardation films made thereby are likely to be contaminated to result in a reduced yield rate.

Moreover, to avoid the aforesaid drawbacks, a photo-alignment method, which is relatively simple, has also been proposed. In the photo-alignment method, liquid crystal molecules are applied onto a photo-alignment layer capable of orienting liquid crystal molecules so that the liquid crystal molecules are oriented in a single direction, followed by curing the same to obtain a retardation film. Besides, a retardation film having two alignment directions can be also produced using the photo-alignment method.

For example, PCT International Publication No. WO2001029148 has disclosed a method of making a retardation film using such photo-alignment method. In this method, a photo-alignment layer is exposed through a patterned mask using a first linearly-polarized UV light having a first polarizing direction for 4 minutes so that a first part of the photo-alignment layer which is exposed to the first linearly-polarizedUV light has a first alignment direction. Then, after removing the patterned mask, the photo-alignment layer is fully exposed to a second linearly-polarized UV light having a second polarizing direction for 30 seconds so that a second part of the photo-alignment layer that was not exposed to the first linearly-polarized UV light has a second alignment direction, thereby rendering the photo-alignment layer to have two different alignment directions. Finally, liquid crystal molecules are coated and cured on the photo-alignment layer, thereby obtaining a retardation film.

In such photo-alignment method, in order to prevent the oriented direction of the first part of the photo-alignment layer from varying due to the second linearly-polarized UV light, an exposure dosage of the first linearly-polarized UV light is normally required to be sufficient to fully cure the first part of the photo-alignment layer.

However, it takes a relatively long time to fully cure the photo-alignment layer since linearly-polarized UV light irradiation devices generally have poor illuminating efficiency relative to general UV light irradiation devices. In addition, it is adverse to a roll to roll continuous production for the retardation films. Besides, linearly-polarized UV light irradiation devices are expensive. If such devices are operated at high power to provide a relatively high exposure dosage, UV light emitting elements used in such devices should be replaced with higher frequency, thereby resulting in increased maintenance cost and energy consumption.

### SUMMARY OF THE INVENTION

Therefore, an object of the present invention is to provide a method for making a retardation film that can overcome the aforesaid drawbacks associated with the prior art.

Accordingly, a method for making a retardation film of this invention comprises:

(a) forming a photo-alignment layer on a substrate, the photo-alignment layer including an alignment surface opposite to the substrate;

(b) exposing the alignment surface using a first linearly-polarized UV light having a first polarizing direction such that first and second regions of the alignment surface are oriented in a first alignment direction;

(c) disposing a patterned mask over the photo-alignment layer such that the first regions of the alignment surface are shielded by the patterned mask;

(d) exposing the second regions of the alignment surface that are not shielded by the patterned mask using a second linearly-polarized UV light having a second polarizing direction that is different from the first polarizing direction such that the second regions of the alignment surface are oriented in a second alignment direction that is different from the first alignment direction, and such that the first regions of the alignment surface remain oriented in the first alignment direction;

(e) coating liquid crystal molecules over the alignment surface, such that the liquid crystal molecules are oriented by the first and second regions of the alignment surface that are respectively oriented in the first and second alignment directions; and

(f) curing the liquid crystal molecules so as to obtain a retardation film having the liquid crystal molecules oriented in two different directions.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic side view illustrating a step of forming a photo-alignment layer on a substrate in a method for making a retardation film according to the preferred embodiment of the present invention;

FIG. 2 is a schematic side view illustrating a step of exposing the photo-alignment layer in the method of the present invention;

FIG. 3 is a schematic side view illustrating a step of exposing the photo-alignment layer through a patterned mask in the method of the present invention;

FIG. 4 is a flow diagram illustrating steps of coating and curing liquid crystal molecules in the method of the present invention; and

FIG. 5 are schematic views illustrating orienting of the photo-alignment layer after an exposing step.

### DETAILED DESCRIPTION OF THE PREFERRED EMBODIMENTS

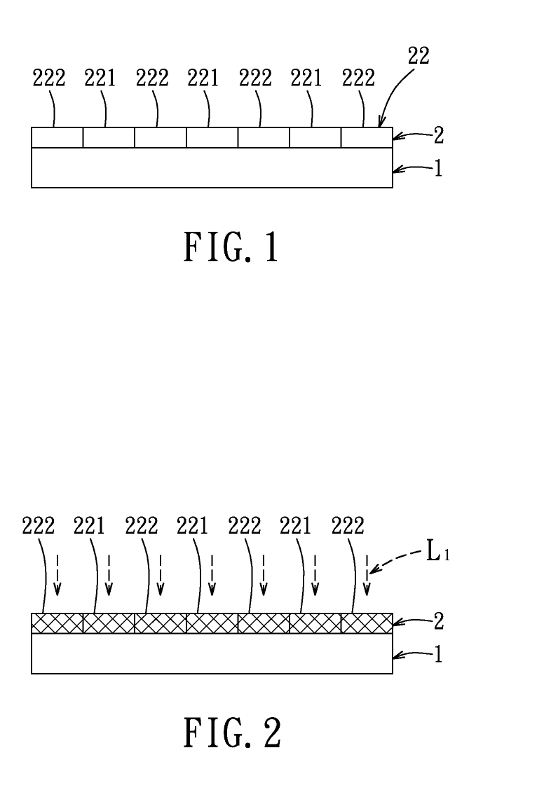

Referring to FIGS. 1-4, the preferred embodiment of a method for making a retardation film of this invention comprises the following steps (a) to (f) in sequence.

In step (a), a photo-alignment layer 2 is formed on a substrate 1. The photo-alignment layer 2 has an alignment surface 22 opposite to the substrate 1 (see FIG. 1). The alignment surface 22 has first and second regions 221, 222.

In step (b), the alignment surface 22 is exposed to a first linearly-polarized UV light (L1) having a first polarizing direction such that the first and second regions 221, 222 of the alignment surface 22 are oriented in a first alignment direction (see FIG. 2).

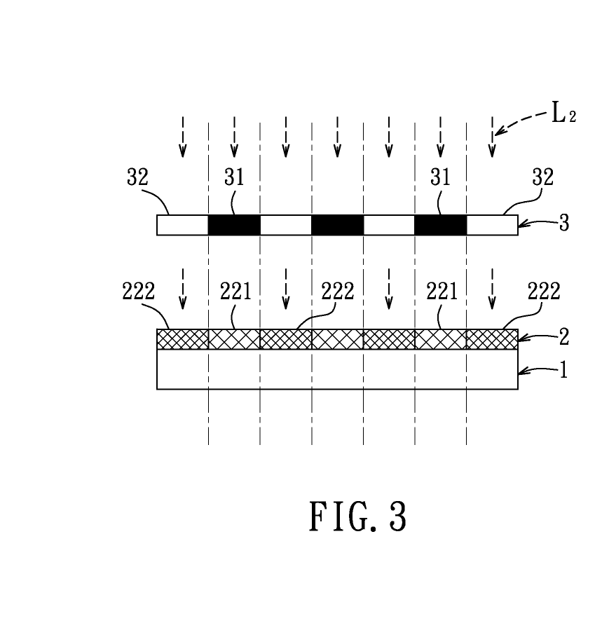

In step (c), a patterned mask 3 is disposed on the photo-alignment layer 2 such that the first regions 221 of the alignment surface 22 are shielded by the patterned mask 3 (see FIG. 3).

Instep (d), the second regions 222 of the alignment surface 22 that are not shielded by the patterned mask 3 are exposed to a second linearly-polarized UV light (L2) having a second polarizing direction that is different from the first polarizing direction, such that the second regions 222 of the alignment surface 22 are oriented in a second alignment direction that is different from the first alignment direction, and such that the first regions 221 of the alignment surface 22 remain oriented in the first alignment direction (see FIG. 3).

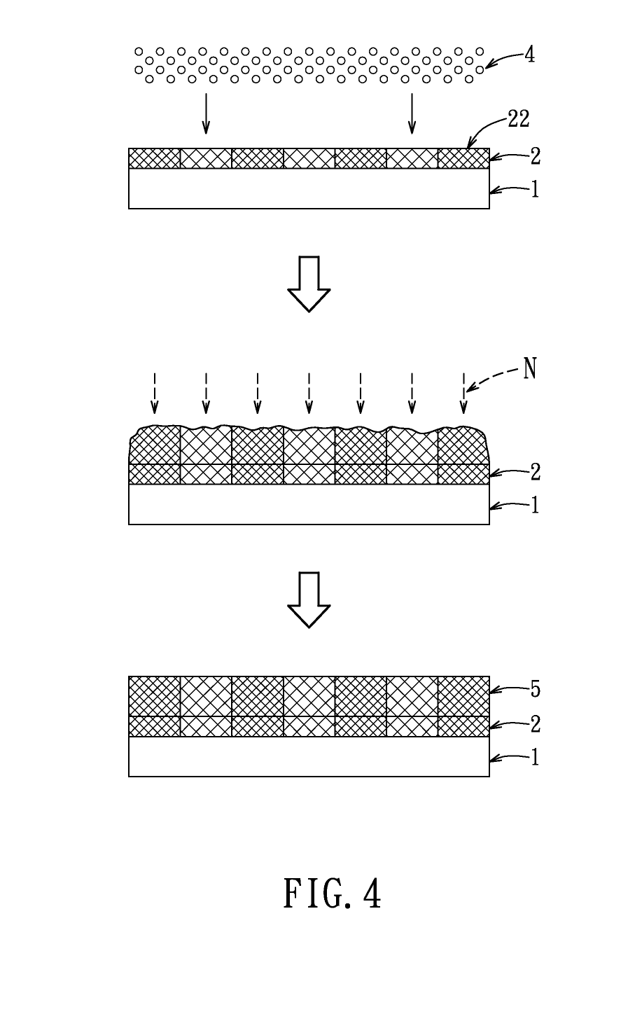

In step (e), the alignment surface 22 having two different alignment directions (i.e., the first and second alignment directions) is coated with liquid crystal molecules 4, such that the liquid crystal molecules 4 are oriented by the first and second regions 221, 222 of the alignment surface 22 that are respectively oriented in the first and second alignment directions (see FIG. 4).

In step (f), the liquid crystal molecules 4 are cured by cross-linking reaction so as to obtain a retardation film 5 having the liquid crystal molecules oriented in two different directions (see FIG. 4).

The photo-alignment layer 2 can be formed by coating the substrate 1 with a photo-alignment material dissolved in a solvent, followed by drying to remove the solvent so as to facilitate subsequent processing or preservation of the photo-alignment layer 2.

The photo-alignment material may be coated on the substrate 1 by any method which may be selected for the sake of working convenience. Non-limiting examples of the coating method include spin coating, bar coating, dip coating, slot coating, roll to roll coating, etc.

A coated thickness of the photo-alignment material is not limited as long as it would not result in an adverse effect for the orientation of the liquid crystal molecules. However, for the sake of working convenience and cost reduction, the coated thickness of the photo-alignment material preferably ranges from 10 nm to 1 μm, and more preferably ranges from 10 nm to 50 nm.

The photo-alignment material can be dried by any device known in the art, such as a hot plate, an oven, a vacuum drying device, etc.

The solvent used for dissolving the photo-alignment material is not limited, and may be selected for facilitating the coating of the photo-alignment material, such as methyl ethyl ketone, cyclopentanone, cyclohexanone, toluene, etc.

The substrate 1 may be made of a material selected from any material commonly used for a substrate of a retardation film. For example, the material of the substrate 1 maybe selected from cellulose-based resin, polyester-based resin, acetate-based resin, polyethersulfone-based resin, polycarbonate-based resin, polyamide-based resin, polyimide-based resin, polyolefin-based resin, acrylic-based resin, polyvinyl chloride-based resin, polystyrene-based resin, polyvinyl alcohol-based resin, polyarylate-based resin, polyphenylene sulfide-based resin, polyvinylidene chloride-based resin, methylacrylic-based resin, etc.

Besides, in order to enhance the working convenience of subsequent processing, and to reduce material cost, the substrate 1 may alternatively be any other optical films for combining to the retardation film. The substrate 1 may be, but is not limited to, a release film, a polarizing plate, a protective film, a diffusing film, a diffusing plate, a light guide plate, a brightness enhancing film, a flexible panel, or a touch panel.

The photo-alignment material is capable of causing photochemical reaction when being exposed to light. Such photochemical reaction can be achieved by one of three mechanisms, i.e., photo-induced isomerization, photo-induced crosslinking, and photo-induced cracking.

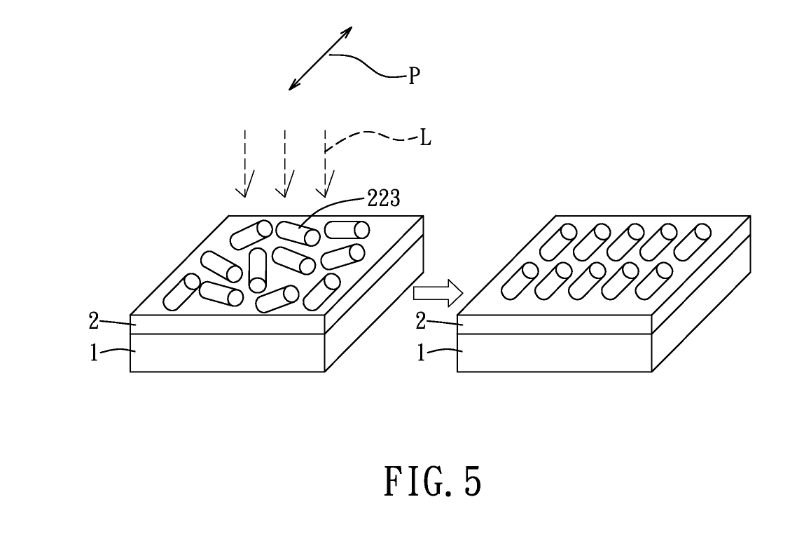

In FIG. 5, the photo-alignment layer 2 is made of a photo-induced crosslinking compound. In this case, molecules 223 of the photo-induced crosslinking compound in the photo-alignment layer 2 are subjected to a crosslinking reaction when being exposed to linearly-polarized UV light (L). In other words, under the influence of the linearly-polarized UV light (L), the molecules 223 are oriented and cured along a predetermined polarizing direction (P).

In this embodiment, the linearly-polarized UV light means a plane-polarized ultraviolet light having a single linearly polarizing direction, and is obtained bypassing a non-polarized UV light through a polarizer (such as a filter, a polarizing film or an optical grid) which permits only one predetermined direction of the polarized light to pass there through. The non-polarized UV light means circularly-polarized UV light that is emitted from a commonly-used UV light source, and that has a homogenous light intensity distribution.

When the photo-alignment layer 2 is made of a photo-induced isomerization compound, in step (b), in order to orient the photo-alignment layer 2 in the first alignment direction at a non-fully cured state, the first linearly-polarized UV light (L1) preferably has a dosage not more than 160 mJ/cm², and more preferably ranging from 10 mJ/cm² to 150 mJ/cm². In this way, because the photo-alignment layer 2 is at the non-fully cured state in step (d), the second regions 222 of the photo-alignment layer 2 can be easily oriented in the second alignment direction in the subsequent processing. Preferably, the photo-induced isomerization compound is an azobenzene-based resin.

In this embodiment, the dosage means a time integration value of the exposure dosage of the linearly-polarized UV light per unit area of the photo-alignment layer 2 in a single exposure.

In the case when the photo-alignment layer 2 is made of a photo-induced crosslinking compound, in step (b), in order to orient the photo-alignment layer 2 in the first alignment direction at a non-fully cured state, the first linearly-polarized UV light (L1) preferably has a dosage not more than 300 mJ/cm², and more preferably ranging from 20 mJ/cm² to 300 mJ/cm², and most preferably ranging from 20 mJ/cm² to 100 mJ/cm². In this way, because the photo-alignment layer 2 is at the non-fully cured state, in step (d), the second regions 222 of the photo-alignment layer 2 can be easily oriented in the second alignment direction in the subsequent processing.

Non-limiting examples of the photo-induced crosslinking compound includes a cinnamate-based resin, coumarin-based resin, chalcone-based resin, maleimide-based resin, quinolinone-based resin, bis(benzylidene)-based resin, etc. In this embodiment, the photo-induced crosslinking compound is a cinnamate-based resin.

In step (d), in order to orient the second regions 222 of the photo-alignment layer 2 in the second alignment direction, the second linearly-polarized UV light (L2) preferably has a dosage not less than that of the first linearly-polarized UV light. More preferably, the second linearly-polarized UV light (L2) has a dosage greater than 1.2 times of that of the first linearly-polarized UV light (L1). However, in order to enhance production efficiency, particularly, in order to reduce energy consumption and the production time, in step (d), the dosage of the second linearly-polarized UV light (L2) is preferably not greater than 500 mJ/cm².

In step (d), only the second regions 222 are exposed to the second linearly-polarized UV light (L2) and oriented in the second alignment direction, while the first regions 221 are not exposed to the second linearly-polarized UV light (L2) and remain oriented in the first alignment direction since the first regions 221 are shielded by the patterned mask 3.

The patterned mask 3 has alternating light transmissive regions 32 and light impermeable regions 31. The light transmissive regions 32 permit passage of the second linearly-polarizedUV light (L2), and the light impermeable regions 31 can block, absorb, or reflect the second linearly-polarized UV light (L2). The patterned mask 3 can be made from any material based on requirements.

In the present invention, the first polarizing direction of the first linearly-polarizedUV light (L1) and the second polarizing direction of the second linearly-polarized UV light (L2) can be two different arbitrary directions. The first and second polarizing directions have an angle e therebetween, and the angle θ preferably ranges from 20° to 90°. More preferably, the angle e is a substantially right angle (i.e., the first and second polarizing directions are substantially perpendicular to each other). Therefore, the retardation film made according to the method of the present invention has two alignment directions which are at substantially right angles to each other. However, the angle e should not be limited to the abovementioned range, and may be outside the abovementioned range depending on requirements.

In step (e), when the liquid crystal molecules 4 are applied to the photo-alignment layer 2 having two alignment directions, van der Waals' forces are created between the liquid crystal molecules 4 and surface molecules of the photo-alignment layer 2, and thus the liquid crystal molecules 4 are oriented in two predetermined directions (i.e., the alignment directions).

The liquid crystal molecules 4 may be selected from any type of liquid crystal material for the sake of working convenience, and may be, for example, photo-induced crosslinking liquid crystal molecules having acrylic acid groups. In the case that the photo-induced crosslinking liquid crystal molecules having acrylic acid groups are used as the liquid crystal molecules 4, the liquid crystal molecules 4 are cured when being exposed to non-polarized UV light (N) (see FIG. 4). This is because the acrylic acid groups, which have unsaturated double bonds, can be used to carry out a photochemical reaction (i.e., a cross-linking reaction) when being exposed to non-polarized UV light. The retardation film 5 having two alignment directions can thus be formed.

A dosage of the non-polarized UV light (N) may be determined according to the type of the liquid crystal molecules 4 and the type of the exposure device. In the present invention, the dosage of the non-polarized UV light (N) should not be limited, as long as the liquid crystal molecules 4 can be cured.

Generally, an exposure efficiency of a non-polarized UV light is several times or even several ten times greater than that of a linearly-polarized UV light. That is to say, the non-polarized UV light (N) has far higher exposure efficiency than those of the first and second linearly-polarized UV lights (L1, L2). Therefore, since the photo-alignment layer 2 is also exposed to the non-polarized UV light (N) in step (f), the photo-alignment layer 2 may also be fully cured in this step. In other words, the photo-alignment layer 2 having the two alignment directions may not be fully cured even after being exposed to the first and second linearly-polarized UV lights (L1, L2), but may be fully cured after being further exposed to the non-polarized UV light (N) in step (f). Besides, in step (e), the photo-alignment layer 2 can be used to orient the liquid crystal molecules 4 whether it is fully cured or not in steps (b) and (d).

The liquid crystal molecules 4 may be coated on the photo-alignment layer 2 by any method selected for the sake of working convenience. Non-limiting examples of the coating method include spin coating, bar coating, dip coating, slot coating, roll to roll coating, etc. Besides, in these methods, the liquid crystal molecules applied to the photo-alignment layer can have an intended thickness by adjusting a spin rate, a bar size, a rotation rate of the rolls, etc.

Additionally, the liquid crystal molecules 4 can be dried after being applied to the photo-alignment layer 2 in step (e). After drying, the solvent contained in the liquid crystal molecules 4 can be removed, thereby facilitating subsequent processing such as curing or preservation. The liquid crystal molecules 4 can be dried by any known device, such as a hot plate, an oven, or a vacuum drying device.

The solvent used for the liquid crystal molecules 4 is not limited, and may be selected for facilitating the coating of the liquid crystal molecules 4. Non-limiting examples of the solvent include methyl ethyl ketone, cyclopentanone, cyclohexanone, toluene, etc.

The present invention will now be explained in more detail below by way of the following examples . It should be noted that the examples are only for exemplification and not for limiting the scope of the present invention.

### EXAMPLE 1

In Example 1, the method for making a retardation film comprises the following steps (a) to (f) in sequence.

In step (a), 1.75 g of methyl ethyl ketone and 1.75 g of cyclopentanone were mixed to obtain a solvent (3.5 g). Then, 0.5 g of an azobenzene-based resin (solid content: 5 wt %, absorption maximum wavelength: 330 to 430 nm) was added into the solvent, so as to obtain 4 g of a photo-alignment resin solution having a solid content of 1.25 wt %.

The photo-alignment resin solution was spin coated on a surface of a substrate made of triacetate cellulose at 3000 rpm for 40 seconds. Then, the substrate coated with the photo-alignment resin solution was disposed in an oven maintained at 100° C. for 2 minutes to remove the solvent, followed by cooling to room temperature to obtain a photo-alignment layer without specific alignment direction.

In step (b), the photo-alignment layer was exposed to a UV light having a polarizing direction of 0 degree (a first linearly-polarized UV light, obtained using a filter which permits light having a wavelength range of 330 to 430 nm to pass there through). The dosage of the first linearly-polarized UV light was 12 mJ/cm², which is equivalent to an exposure of 12 seconds at an exposure intensity of 1 mW/cm².

In step (c), the photo-alignment layer exposed to the first linearly-polarized UV light in step (b) was covered with a patterned mask which has a line-spacing width of 350 μm.

In step (d), the photo-alignment layer was further exposed to a UV light having a polarizing direction of 90 degrees (a second linearly-polarized UV light, obtained using a filter which permits light having a wavelength range of 330 to 430 nm to pass there through). The dosage of the second linearly-polarized UV light was 12 mJ/cm². At this time, a part of the alignment surface on the photo-alignment layer which was shielded by the patterned mask serves as the first regions, and another part of the alignment surface, which was not shielded by the patterned mask, serves as the second regions.

In step (e), 1 g of photo-induced crosslinking solid liquid crystal molecules (available from BASF, trade name: LC242, birefringence: 0.14) was added into 4 g of cyclopentanone to obtain a liquid crystal solution having a solid content of 20 wt %. The liquid crystal solution was spin coated on the photo-alignment layer at 3000 rpm for 40 seconds.

In step (f), the substrate coated with the photo-alignment layer and the liquid crystal solution was disposed in an oven maintained at 60° C. for 5 minutes to remove the solvent (i.e., cyclopentanone), and thus a liquid crystal layer was formed on the photo-alignment layer. Then, the substrate was cooled to room temperature and exposed to UV light at a dosage of 120 mJ/cm² in a nitrogen atmosphere. Accordingly, a retardation film of Example 1 was obtained.

### EXAMPLE 2

In Example 2, the retardation film was obtainedbased on the procedure employed in Example 1 except that, in step (d), the photo-alignment layer was exposed to the second linearly-polarized UV light at a dosage of 25 mJ/cm².

### EXAMPLE 3

In Example 3, the retardation film was obtainedbased on the procedure employed in Example 1 except that, in step (b), the photo-alignment layer was exposed to the first linearly-polarized UV light at a dosage of 45 mJ/cm², which is equivalent to an exposure of 45 seconds at an exposure intensity of 1 mW/cm², and in step (d), the photo-alignment layer was exposed to the second linearly-polarized UV light at a dosage of 90 mJ/cm².

### EXAMPLE 4

In Example 4, the retardation film was obtainedbased on the procedure employed in Example 1 except that, in step (b), the photo-alignment layer was exposed to the first linearly-polarized UV light at a dosage of 90 mJ/cm², which is equivalent to an exposure of 90 seconds at an exposure intensity of 1 mW/cm², and in step (d), the photo-alignment layer was exposed to the second linearly-polarized UV light at a dosage of 90 mJ/cm2.

### EXAMPLE 5

In Example 5, the retardation film was obtainedbased on the procedure employed in Example 1 except that, in step (b), the photo-alignment layer was exposed to the first linearly-polarized UV light at a dosage of 135 mJ/cm², which is equivalent to an exposure of 135 seconds at an exposure intensity of 1 mW/cm², and in step (d), the photo-alignment layer was exposed to the second linearly-polarized UV light at a dosage of 215 mJ/cm².

### EXAMPLE 6

In Example 6, the retardation film was obtainedbased on the procedure employed in Example 1 except that, in step (b), the photo-alignment layer was exposed to the first linearly-polarized UV light at a dosage of 145 mJ/cm², which is equivalent to an exposure of 145 seconds at an exposure intensity of 1 mW/cm², and in step (d), the photo-alignment layer was exposed to the second linearly-polarized UV light at a dosage of 250 mJ/cm².

### COMPARATIVE EXAMPLE 1

In Comparative Example 1, the retardation film was obtained based on the procedure employed in Example 1 except that, instep (b), the photo-alignment layer was exposed to the first linearly-polarized UV light at a dosage of 6 mJ/cm², which is equivalent to an exposure of 6 seconds at an exposure intensity of 1 mW/cm². Besides, in Comparative Example 1, step (c) and (d) were omitted. Thus, after step (b), step (e) followed.

### COMPARATIVE EXAMPLE 2

In Comparative Example 2, the retardation film was obtained based on the procedure employed in Example 1 except that, instep (b), the photo-alignment layer was exposed to the first linearly-polarized UV light at a dosage of 165 mJ/cm², which is equivalent to an exposure of 165 seconds at an exposure intensity of 1 mW/cm², and in step (d), the photo-alignment layer was exposed to the second linearly-polarized UV light at a dosage of 250 mJ/cm².

### COMPARATIVE EXAMPLE 3

In Comparative Example 3, the retardation film was obtained based on the procedure employed in Example 1 except that, instep (b), the photo-alignment layer was exposed to the first linearly-polarized UV light at a dosage of 90 mJ/cm², which is equivalent to an exposure of 90 seconds at an exposure intensity of 1 mW/cm², and in step (d), the photo-alignment layer was exposed to the second linearly-polarized UV light at a dosage of 45 mJ/cm².

Measurement of the Alignment Directions of the Liquid Crystal Molecules

The alignment direction of each of the first and second regions of the retardation films respectively made in Examples 1-6 and Comparative Examples 1-3 was measured using a polarization microscope (available from Oji Scientific Instruments, trade name: KOBRA-CCD). The measurement results and the dosages in Examples 1-6 and Comparative Examples 1-3 are listed in Table 1.

TABLE 1

| | Dosage of the | Dosage of the | Alignment | Alignment |
|---|---|---|---|---|
| | first linearly- | second linearly- | direction | direction |
| | polarized | polarized | of the first | of the first |
| | UV light | UV light | regions | regions |
| | (mJ/cm²) | (mJ/cm²) | (degrees) | (degrees) |
| Ex. 1 | 12 | 12 | 0 | 90 |
| Ex. 2 | 12 | 25 | 0 | 90 |
| Ex. 3 | 45 | 90 | 0 | 90 |
| Ex. 4 | 90 | 90 | 0 | 90 |
| Ex. 5 | 135 | 215 | 0 | 90 |
| Ex. 6 | 145 | 250 | 0 | 90 |
| CE. 1 | 6 | — | No | No |
| | | | alignment | alignment |
| | | | direction | direction |
| CE. 2 | 165 | 250 | 0 | 0 |
| CE. 3 | 90 | 45 | 0 | 0 |

According to the results of Examples 1-6 shown in Table 1, in step (d), each of the alignment directions of the second regions was changed from 0 degree to 90 degrees, while those of the first regions remained at 0 degree. Therefore, after step (f), the retardation films each having two different alignment directions were obtained in Examples 1-6.

Furthermore, according to the result of Comparative Example 1 shown in Table 1, it is noted that if the dosage of the first linearly-polarized UV light is too low, the liquid crystal molecules cannot be oriented in a specific direction.

On the contrary, according to the result of Comparative Example 2 shown in Table 1, it is noted that if the dosage of the first linearly-polarized UV light is too high, the whole regions of the photo-alignment layer (i.e., the first and second regions) would be fully cured and oriented in a specific alignment direction (0 degree, in this example). Therefore, even if the photo-alignment layer is exposed to the second linearly-polarized UV light in step (d), the alignment direction would not be changed. Besides, in order to achieve suchhigh dosage of the first linearly-polarized UV light, the exposure time is likely to be long.

Similarly, according to the result of Comparative Example 3 shown in Table 1, it is noted that if the dosage of the second linearly-polarized UV light of step (d) is lower than that of the first linearly-polarized UV light of step (b), the alignment direction of the second regions would not be changed and still remain at 0 degree even after being exposed to the second linearly-polarized UV light in step (d).

### EXAMPLE 7

In Example 7, the retardation film was obtained based on the procedure employed in Example 1 except that, in step (a), a cinnamate-based resin (solid content: 10 wt %, absorption maximum wavelength: 250 to 350 nm) was usedinsteadofthe azobenzene-based resin. In step (b), the photo-alignment layer was exposed to the first linearly-polarized UV light at a dosage of 25 mJ/cm², which is equivalent to an exposure of 25 seconds at an exposure intensity of 1 mW/cm². In step (d), the photo-alignment layer was exposed to the second linearly-polarized UV light at a dosage of 30 mJ/cm². Besides, the filters, which are respectively used to obtain the first and second linearly-polarizedUV light, permit light having a wavelength range of 250 to 350 nm to pass there through.

### EXAMPLE 8

In Example 8, the retardation film was obtainedbased on the procedure employed in Example 7 except that, in step (d), the photo-alignment layer was exposed to the second linearly-polarized UV light at a dosage of 50 mJ/cm².

### EXAMPLE 9

In Example 9, the retardation film was obtainedbased on the procedure employed in Example 7 except that, in step (b), the photo-alignment layer was exposed to the first linearly-polarized UV light at a dosage of 90 mJ/cm², which is equivalent to an exposure of 90 seconds at an exposure intensity of 1 mW/cm², and in step (d), the photo-alignment layer was exposed to the second linearly-polarized UV light at a dosage of 180 mJ/cm².

### COMPARATIVE EXAMPLE 4

In Comparative Example 4, the retardation film was obtained based on the procedure employed in Example 7 except that, in step (b), the photo-alignment layer was exposed to the first linearly-polarized UV light at a dosage of 15 mJ/cm², which is equivalent to an exposure of 15 seconds at an exposure intensity of 1 mW/cm². Besides, in Comparative Example 4, step (c) and (d) were omitted. Thus, after step (b), step (e) followed.

### COMPARATIVE EXAMPLE 5

In Comparative Example 5, the retardation film was obtained based on the procedure employed in Example 7 except that, in step (b), the photo-alignment layer was exposed to the first linearly-polarized UV light at a dosage of 330 mJ/cm², which is equivalent to an exposure of 330 seconds at an exposure intensity of 1 mW/cm², and in step (d), the photo-alignment layer was exposed to the second linearly-polarized UV light at a dosage of 500 mJ/cm².

### COMPARATIVE EXAMPLE 6

In Comparative Example 6, the retardation film was obtained based on the procedure employed in Example 7 except that, in step (b), the photo-alignment layer was exposed to the first linearly-polarized UV light at a dosage of 180 mJ/cm², which is equivalent to an exposure of 180 seconds at an exposure intensity of 1 mW/cm², and in step (d), the photo-alignment layer was exposed to the second linearly-polarized UV light at a dosage of 90 mJ/cm².

Measurement of the Alignment Directions of the Liquid Crystal Molecules

The alignment direction of each of the first and second regions of the retardation films respectively made in Examples 7-9 and Comparative Examples 4-6 was measured using the polarization microscope. The measurement results and the dosages in Examples 7-9 and Comparative Examples 4-6 are listed in Table 2.

TABLE 2

| | Dosage of the | Dosage of the | Alignment | Alignment |
|---|---|---|---|---|
| | first linearly- | second linearly- | direction | direction |
| | polarized | polarized | of the first | of the first |
| | UV light | UV light | regions | regions |
| | (mJ/cm²) | (mJ/cm²) | (degrees) | (degrees) |
| Ex. 7 | 25 | 30 | 0 | 90 |
| Ex. 8 | 25 | 50 | 0 | 90 |
| Ex. 9 | 90 | 180 | 0 | 90 |
| CE. 4 | 15 | — | No | No |
| | | | alignment | alignment |
| | | | direction | direction |
| CE. 5 | 330 | 500 | 0 | 0 |
| CE. 6 | 180 | 90 | 0 | 0 |

According to the results of Examples 7-9 shown in Table 2, in step (d), each of the alignment directions of the second regions was changed from 0 degree to 90 degrees, while those of the first regions remained at 0 degree. Therefore, after step (f), the retardation films each having two different alignment directions were obtained in Examples 7-9. It is found that even if the photo-alignment materials for forming the photo-alignment layers are different (see Examples 1-6 and Examples 7-9), the retardation films each having two different alignment directions can be obtained by virtue of the method for making a retardation film according to the present invention.

In Comparative Examples 4-6, similar to Comparative Examples 1-3, a retardation film having two different alignment directions was not obtained.

Furthermore, compared to the method disclosed in PCT International Publication No. WO2001029148, in which a total UV exposure time for forming a photo-alignment layer is 4.5 minutes, the total exposure time in the method of the present invention may be shortened to 2 minutes or less (see Examples 1,2,7 and 8). Thus, the exposure efficiency of the method of the present invention may be twice better than that of the conventional method. Especially, in Example 1, the exposure efficiency was increased about 10 times of that of the conventional method. When forming a retardation film using the method according to the present invention, energy consumption may be reduced, and production efficiency may be enhanced.

To summarize, according to the method for making a retardation film of the present invention, because the photo-alignment layer 2 is not fully cured (i.e., the alignment direction is not fixed) in step (b), the exposure time of the first linearly-polarized UV light can be efficiently shortened, thereby reducing production time and energy consumption.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A method for making a retardation film, comprising:
(a) forming a photo-alignment layer on a substrate, the photo-alignment layer including an alignment surface opposite to the substrate;
(b) exposing the alignment surface using a first linearly-polarized UV light having a first polarizing direction such that first and second regions of the alignment surface are oriented in a first alignment direction;
(c) disposing a patterned mask over the photo-alignment layer such that the first regions of the alignment surface are shielded by the patterned mask;
(d) exposing the second regions of the alignment surface that are not shielded by the patterned mask using a second linearly-polarized UV light having a second polarizing direction that is different from the first polarizing direction such that the second regions of the alignment surface are oriented in a second alignment direction that is different from the first alignment direction, and the first regions of the alignment surface remain oriented in the first alignment direction;
(e) coating liquid crystal molecules over the alignment surface, such that the liquid crystal molecules are oriented by the first and second regions of the alignment surface that are respectively oriented in the first and second alignment directions; and
(f) curing the liquid crystal molecules so as to obtain a retardation film having the liquid crystal molecules oriented in two different directions.

2. The method of claim 1, wherein the substrate is made of a material selected from the group consisting of cellulose-based resin, polyester-based resin, acetate-based resin, polyethersulfone-based resin, polycarbonate-based resin, polyamide-based resin, polyimide-based resin, polyolefin-based resin, acrylic-based resin, polyvinyl chloride-based resin, polystyrene-based resin, polyvinyl alcohol-based resin, polyarylate-based resin, polyphenylene sulfide-based resin, polyvinylidene chloride-based resin, and methacrylate-based resin.

3. The method of claim 1, wherein the substrate is selected from the group consisting of a release film, a polarizing plate, a protective film, a diffusing film, a diffusing plate, a light guide plate, a brightness enhancing film, a flexible panel, and a touch panel.

4. The method of claim 1, wherein the photo-alignment layer is made of a photo-induced isomerization compound.

5. The method of claim 4, wherein the photo-alignment layer is made of an azobenzene-based resin.

6. The method of claim 4, wherein, instep (b), the first linearly-polarized UV light has a dosage not more than 160 mJ/cm².

7. The method of claim 4, wherein, instep (b), the first linearly-polarized UV light has a dosage ranging from 10 mJ/cm² to 150 mJ/cm².

8. The method of claim 1, wherein the photo-alignment layer is made of a photo-induced crosslinking compound.

9. The method of claim 8, wherein the photo-alignment layer is made of a cinnamate-based resin.

10. The method of claim 8, wherein, in step (b), the first linearly-polarized UV light has a dosage not more than 300 mJ/cm².

11. The method of claim 8, wherein, in step (b), the first linearly-polarized UV light has a dosage ranging from 20 mJ/cm² to 300 mJ/cm².

12. The method of claim 8, wherein, in step (b), the first linearly-polarized UV light has a dosage ranging from 20 mJ/cm² to 100 mJ/cm².

13. The method of claim 1, wherein, in step (d), the second linearly-polarized UV light has a dosage not less than that of the first linearly-polarized UV light.

14. The method of claim 13, wherein, in step (d), the second linearly-polarized UV light has a dosage not more than 500 mJ/cm².

15. The method of claim 1, wherein the first and second polarizing directions have an angle therebetween, the angle ranging from 20° to 90° .

16. The method of claim 1, wherein the first and second polarizing directions have a substantially right angle therebetween.
